(19) United States
(12) Patent Application Publication
(10) Pub. No.: US 2010/0327774 A1
(43) Pub. Date: Dec. 30, 2010

(54) Housing Illumination for Portable Electronic Devices

(76) Inventors: Duncan Robert Kerr, San Francisco, CA (US); Nick King, San Jose, CA (US)

Correspondence Address: TI Law Group, 2055 Junction Avenue, #205, San Jose, CA, 95131-2116, US

(21) Appl. No.: 12/495,483

(22) Filed: Jun. 30, 2009

(51) Int. Cl. H05B 41/36; H05K 5/00; G06F 1/16

(52) U.S. Cl. 315/307; 361/679.01; 361/679.02; 315/291

(57) ABSTRACT

Systems, devices and methods for electronically marking a housing of a portable electronic device are disclosed. When the housing of the portable electronic device is electronically marked, the marking(s) are non-permanent and able to be rapidly and dynamically changed. The marked housing can provide notification or guidance to a user. The housing can also be electronically marked in a manner that facilitates low power operation of the portable electronic device. The portable electronic device can, for example, be a mobile phone (e.g., cell phone), a personal digital assistant (PDA), a computer peripheral (e.g., mouse), a portable media player, and the like.

### BACKGROUND OF THE INVENTION

1. Field of the Invention

The present invention relates to illumination of portable electronic devices and, more particularly, to illumination of portable electronic device housings.

2. Description of the Related Art

Conventionally, computers are contained within structures is referred to as boxes, enclosures, casings or the like. Traditionally, these structures are made of plastic or metal. Often, the structures include openings for buttons, disk drives, connectors/ports, displays, and status light emitting diodes (LEDs). Peripheral devices, such as a mouse or trackball, typically do not include light emitting features. However, in the case of an optical mouse, an optical element is used for optical tracking. More recently, computers or peripherals in limited cases have used lighting for ornamental or operational features. For example, in the case of a peripheral device, such as a mouse, it is known to utilize a light (e.g., LED) to indicate that the mouse is operational for use with its host computer. Computers can themselves also utilize one more lights to produce ornamental or aesthetic effects. For example, U.S. Pat. No. 7,452,098 describes various embodiments of computers that can utilize light.

Unfortunately, however, conventional uses of lighting for computers and their peripheral devices are static and not well suited to convey dynamic data. Moreover, conventional uses of lighting for computers, such as desktop computers, are not well suited for portable electronic devices, such as handheld devices. Accordingly, their remains a need for improved approaches to provide illumination to portable electronic devices.

### SUMMARY

The invention relates to a system, device and method for electronically marking a housing of a portable electronic device. When the housing of the portable electronic device is electronically marked, the marking(s) are non-permanent and able to be rapidly and dynamically changed. The marked housing can provide notification or guidance to a user. The housing can also be electronically marked in a manner that facilitates low power operation of the portable electronic device. The portable electronic device can, for example, pertain to a mobile phone (e.g., cell phone), a personal digital assistant (PDA), a computer peripheral, a portable media player, and the like.

One aspect of the invention pertains to marking (e.g., illuminating) housings of portable electronic devices to provide notifications to users of portable electronic devices. The notifications are visual notifications and serve to alert users of conditions, status or events of portable electronic devices. In one embodiment, notifications are able to be provided to users of portable electronic devices in a low power manner which is particularly advantageous for battery-powered devices. The content of the notifications can very widely depending upon implementation. One example of notification content pertains to battery status, such as battery charge level, battery charging, etc. Other examples of notification content are a call indicator, message alert and/or a chat session request for a portable electronic device operable as a wireless communication device. Still another example of notification content is clock or date content. The notification content can be displayed on a housing of a portable electronic device. The notification content can include text and/or graphics.

Another aspect of the invention pertains to marking (e.g., illuminating) housings of portable electronic devices to provide guidance to users of portable electronic devices. The guidance is provided in a visual manner to the users. In one embodiment, the guidance can be provided to users of portable electronic devices in a low power manner which is particularly advantageous for battery-powered devices. The content of the guidance can very widely depending upon implementation. One example of guidance content pertains to user input assistance, including a configuration indication, orientation indication, gesture assistance, user input feedback, etc. The guidance content can be displayed on a housing of a portable electronic device. The guidance content can include text and/or graphics.

The notification or guidance being provided by marking (e.g., illumination) of a housing can be initiated by a user of a portable electronic device or by another electronic device in wireless communication with the portable electronic device. The notification or guidance can also be initiated by conditions detected by one or more sensors at the portable electronic device. For example, a motion sensor provided at or within the portable electronic device can be used to activate at least one notification when the portable electronic device is moved. As another example, a touch sensor provided at or within the portable electronic device can be used to activate at least one notification when the portable electronic device is touched.

The invention can be implemented in numerous ways, including as a method, system, device, apparatus (including computer readable medium and graphical user interface). Several embodiments of the invention are discussed below.

As a method for utilizing an outer surface of a housing of a portable electronic device, one embodiment of the invention can, for example, include at least the acts of: receiving a notification request; obtaining notification data; and presenting the notification data to the user of the portable electronic device using a portion of the outer surface of the housing of the portable electronic device.

As a method for marking a portion of a portable device capable of receiving user input, one embodiment of the invention can, for example, include at least the acts of: receiving an event at the portable device; determining whether non-permanent marking imposed on the housing of the portable device is affected by the event; and configuring a marking effect for a portion of the housing of the portable device if the non-permanent marking imposed on the housing of the portable device is affected by the event, the marking effect providing non-permanent marking to the portion of the housing of the portable device.

As a method for illuminating a portion of a portable device capable of receiving user input, one embodiment of the invention can, for example, include at least the acts of: receiving an event at the portable device; determining whether auxiliary illumination imposed on the housing of the portable device is affected by the event; and configuring an illumination effect for a portion of the housing of the portable device if the auxiliary illumination imposed on the housing of the portable device is affected by the event, the illumination effect providing auxiliary illumination to the portion of the housing of the portable device.

As a portable electronic device, one embodiment of the invention can, for example, include at least: a housing for said portable electronic device; at least one light source on or internal to the housing; and an illumination controller operatively connected to the at least one light source. The illumination controller is configured to dynamically control the at least one light source to illuminate a portion of the housing.

As a method for marking an outer surface of a housing of a peripheral user input device for use with a computer, one embodiment of the invention can, for example, include at least the acts of: receiving a marking request from the computer; and electronically marking a portion of the outer surface of the housing of the peripheral user input device in response to the received marking request.

As a method for marking an outer surface of a housing of a peripheral user input device for use with a computer, one embodiment of the invention can, for example, include at least the acts of: receiving a sensor input from a sensor provided with the peripheral user input device; and electronically marking a portion of the outer surface of the housing of the peripheral user input device based on the received sensor input.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like elements, and in which:

FIG. 1A is a block diagram of a housing marking system according to one embodiment of the invention.

FIG. 1B is a block diagram of a housing illumination system according to one embodiment of the invention.

FIG. 2 is a block diagram of a housing illumination system according to one embodiment of the invention.

FIG. 3A is a simplified cross-sectional view of a housing illumination arrangement for a portable electronic device according to one embodiment.

FIG. 3B is a simplified cross-sectional view of a housing illumination arrangement for a portable electronic device according to another embodiment.

FIG. 3C is a simplified cross-sectional view of a housing illumination arrangement for a portable electronic device according to another embodiment.

FIG. 4 is a flow diagram of a notification process according to one embodiment of the invention.

FIG. 5 is a flow diagram of the notification process according to another embodiment of the invention.

FIG. 6 is diagram describing information that can be illuminated by way of a housing on a portable electronic device.

FIG. 7 is a flow diagram of a housing illumination process according to one embodiment of the invention.

FIG. 8 is a flow diagram of a housing illumination process according to another embodiment of the invention.

FIG. 9 is a flow diagram of a host illumination process according to one embodiment of the invention.

FIG. 10 is a flow diagram of a peripheral illumination process according to one embodiment of the invention.

FIGS. 11A-11J are diagrams illustrating exemplary illuminations that can be provided on a housing of a portable electronic device according to various embodiments.

### DETAILED DESCRIPTION OF THE INVENTION

The invention relates to a system, device and method for electronically marking a housing of a portable electronic device. When the housing of the portable electronic device is electronically marked, the marking(s) are non-permanent and able to be rapidly and dynamically changed. The marked housing can provide notification or guidance to a user. The housing can also be electronically marked in a manner that facilitates low power operation of the portable electronic device. The portable electronic device can, for example, pertain to a mobile phone (e.g., cell phone), a personal digital assistant (PDA), a computer peripheral, a portable media player, and the like.

One aspect of the invention pertains to marking (e.g., illuminating) housings of portable electronic devices to provide notifications to users of portable electronic devices. The notifications are visual notifications and serve to alert users of conditions, status or events of portable electronic devices. In one embodiment, notifications are able to be provided to users of portable electronic devices in a low power manner which is particularly advantageous for battery-powered devices. The content of the notifications can very widely depending upon implementation. One example of notification content pertains to battery status, such as battery charge level, battery charging, etc. Other examples of notification content are a call indicator, message alert and/or a chat session request for a portable electronic device operable as a wireless communication device. Still another example of notification content is clock or date content. The notification content can be displayed on a housing of a portable electronic device. The notification content can include text and/or graphics.

Another aspect of the invention pertains to marking (e.g., illuminating) housings of portable electronic devices to provide guidance to users of portable electronic devices. The guidance is provided in a visual manner to the users. In one embodiment, the guidance can be provided to users of portable electronic devices in a low power manner which is particularly advantageous for battery-powered devices. The content of the guidance can very widely depending upon implementation. One example of guidance content pertains to user input assistance, including a configuration indication, orientation indication, gesture assistance, user input feedback, etc. The guidance content can be displayed on a housing of a portable electronic device. The guidance content can include text and/or graphics.

The notification or guidance being provided by marking (e.g., illumination) of a housing can be initiated by a user of a portable electronic device or by another electronic device in wireless communication with the portable electronic device. The notification or guidance can also be initiated by conditions detected by one or more sensors at the portable electronic device. For example, a motion sensor provided at or within the portable electronic device can be used to activate at least one notification when the portable electronic device is moved. As another example, a touch sensor provided at or within the portable electronic device can be used to activate at least one notification when the portable electronic device is touched.

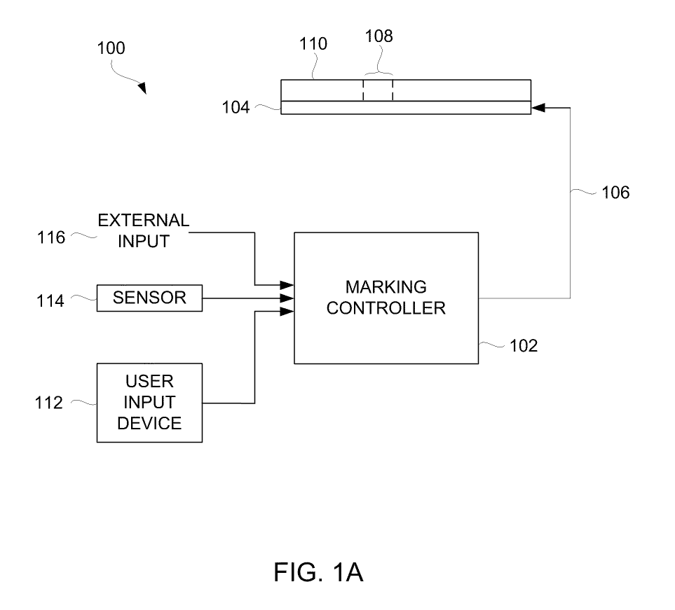

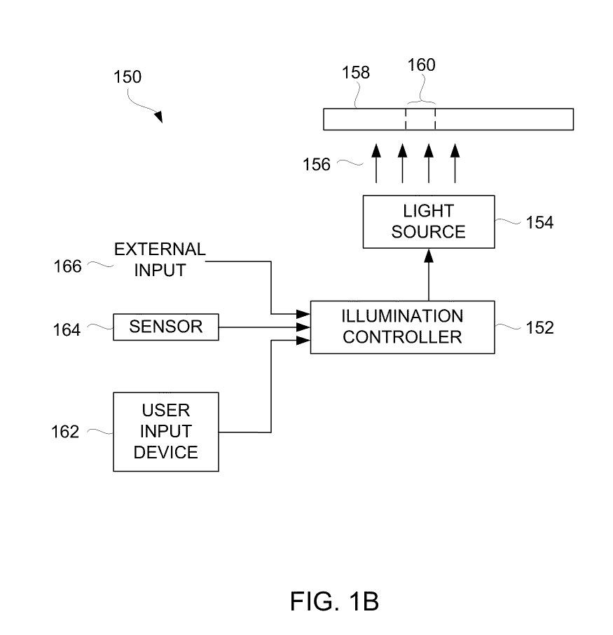

Embodiments of various aspects of the invention are discussed below with reference to FIGS. 1A-11J. However, those skilled in the art will readily appreciate that the detailed description given herein with respect to these figures is for explanatory purposes as the invention extends beyond these limited embodiments.

Embodiments of the invention can operate to electronically mark housings of electronic devices. The electronic marking can dynamically provide non-permanent markings on the housings. Such markings are electronically controlled and therefore readily changeable and able to be dynamic. In one embodiment, a housing for an electronic device can be electronically marked by selectively illuminating one or more areas of a housing. In one embodiment, the marking(s) can be provided with high resolution, such as 100 dots per inch (dpi) or more.

FIG. 1A is a block diagram of a housing marking system 100 according to one embodiment of the invention. The housing marking system 100 operates to mark some portion of a housing of a portable electronic device. The marking is non-permanent and electronically controlled. The marking can, for example, provide notifications or guidance to a user of the portable electronic device. In one embodiment, the portable electronic device is small, lightweight and handheld. Examples of small, lightweight and handheld portable electronic devices include mobile telephones (cellular phones), personal digital assistants (PDAs), remote controllers, user input devices (mice, trackballs, touchpads), or the like.

The housing marking system 100 includes a marking controller 102. The marking controller 102 controls the overall operation with regard to marking of a portion of the housing of the portable electronic device. The marking can provide notification or guidance to a user. The marking controller 102 couples to and controls at least one electronic marking device 104. The marking controller 102 provides a marking control signal 106 to the electronic marking device 104. Under the control of the marking controller 102 (based on the marking control signal 106), the at least one electronic marking device 104 can, at appropriate times, produce one or more markings 108 that are visible on a housing surface 110. The marking can be provided on, in or through the housing surface 110. The characteristics of the one or more markings 108 can be varied depending upon the nature of the marking to be provided. For example, characteristics of the one or more markings 108 can correspond to graphics and/or text. A graphic can pertain to a logo, picture, symbol, drawing, animation, slideshow, etc. The graphics and/or text can operate as a notification to the user of the portable electronic device or can operate as guidance to the user of the portable electronic device. The graphics and/or text can also be provided in one or more colors.

The housing marking system 100 can further include or couple to a user input device 112. The user input device 112 can pertain to a mouse, trackball, track pad, touch surface or the like that facilitates a user with providing input to the housing marking system 100. For example, if the housing marking system 100 is utilized with a portable electronic device operating as a user input device for a host computer, then the housing marking system 100 can interact with the user input device 112. As an example, the housing marking system 100 can display configuration information for the portable electronic device serving as a user input device, or can provide the user with feedback regarding user inputs that have been received by the user input device 112.

Additionally or alternatively, the housing marking system 100 can also include or couple to a sensor 114. The sensor 114 can, for example, be a motion sensor that provides movement information to the marking controller 102. The marking controller 102 can then operate to control marking of the housing surface 110 based on the movement information. In one implementation, the sensor 114 can signal the marking controller 102 that the portable electronic device as recently been moved, whereby the marking controller 102 can initiate marking of the housing surface 110 to signal that the portable electronic device is active or has awaken, or to provide guidance or user assistance on the portable electronic device when being used (e.g., indicate direction of orientation for usage). In one embodiment, the sensor 114 can utilize at least one accelerometer.

Additionally or alternatively, the housing marking system 100 can also receive an external input 116. The external input 116 can be supplied to the marking controller 102. The marking controller 102 can then evaluate the external input 116 and take appropriate action to control marking of the housing surface 110. As an example, the external input 116 can be provided by a host device, such as a host computer. The external input 116 can include a command or request from the host device to the portable electronic device, which can act as a peripheral device for the host device. In one embodiment, to receive the external input 116, the housing marking system 100, or the portable electronic device itself, can include an input/output communication controller.

FIG. 1B is a block diagram of a housing illumination system 150 according to one embodiment of the invention. The housing illumination system 150 operates to illuminate some portion of a housing of a portable electronic device. The illumination can, for example, provide notifications or guidance to a user of the portable electronic device. The portable electronic device is typically small, lightweight and handheld. Examples of small, lightweight and handheld portable electronic devices include mobile telephones (cellular phones), personal digital assistants (PDAs), remote controllers, user input devices (mice, trackballs, touchpads), or the like.

The housing illumination system 150 includes an illumination controller 152. The illumination controller 152 controls the overall operation with regard to illumination of a portion of the housing of the portable electronic device. As previously noted, the illumination can provide notification or guidance to a user. The illumination controller 152 couples to and controls at least one light source 154. Under the control of the illumination controller 152, the at least one light source 154 can, at appropriate times, produce light 156. The light can be patterned in that the at least one light source 154 can be selectively controlled to produce light 156 in a particular pattern or at least confined to a particular region. The light 156 can be directed towards a housing surface 158. The light 156 operates to yield an illuminated portion 160 of the housing surface 158. In this embodiment, a portion of the light 156 passes through the housing surface 158 to cause illumination of the illuminated portion 160. However, in other embodiments, the light source 156 can be internal to, on top of, or integral with the housing surface 158.

The characteristics of the illuminated portion 160 can be varied depending upon the nature of the illumination to be provided. For example, characteristics of the illuminated portion 160 can correspond to graphics and/or text. A graphic can pertain to a logo, picture, symbol, drawing, animation, slideshow, etc. The graphics and/or text can operate as a notification to the user of the portable electronic device or can operate as guidance to the user of the portable electronic device. The at least one light source 156 can also provide the light 156 in one or more colors, such that the illuminated portion 160 can exhibit one or more colors.

The housing illumination system 150 can further include or couple to a user input device 162. The user input device 162 can pertain to a mouse, trackball, track pad, touch surface or the like that facilitates a user with providing input to the housing illumination system 150. For example, if the housing illumination system 150 is utilized with a portable electronic device operating as a user input device for a host computer, then the housing illumination system 150 can interact with the user input device 162. As an example, the housing illumination system 150 can display configuration information for the portable electronic device serving as a user input device, or can provide the user with feedback regarding user inputs that have been received by the user input device 162.

Additionally or alternatively, the housing illumination system 150 can also include or couple to a sensor 164. The sensor 164 can, for example, be a motion sensor that provides movement information to the illumination controller 152. The illumination controller 152 can then operate to control illumination of the housing surface 158 using the light source 154 based on the movement information. In one implementation, the sensor 164 can signal the illumination controller 152 that the portable electronic device as recently been moved, whereby the illumination controller 152 can initiate illumination to signal that the portable electronic device is active or has awaken, or to provide guidance or user assistance on the portable electronic device when being used (e.g., indicate direction of orientation for usage). In one embodiment, the sensor 164 can utilize at least one accelerometer.

Additionally or alternatively, the housing illumination system 150 can also receive an external input 166. The external input 166 can be supplied to the illumination controller 152. The illumination controller 152 can then evaluate the external input 166 and take appropriate action to control illumination of the housing surface 158. As an example, the external input 166 can be provided by a host device, such as a host computer. The external input 166 can include a command or request from the host device to the portable electronic device, which can act as a peripheral device for the host device. In one embodiment, to receive the external input 166, the housing illumination system 150, or the portable electronic device itself, can include an input/output communication controller.

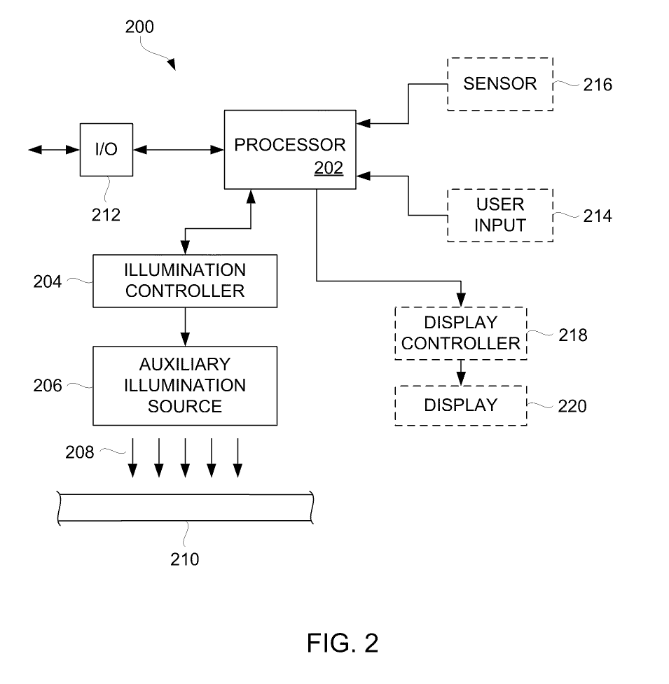

FIG. 2 is a block diagram of a housing illumination system 200 according to one embodiment of the invention. The housing illumination system 200 operates to illuminate a portion of a housing of a portable electronic device.

The housing illumination system 200 can be provided in a portable electronic device having a display for presenting one or more graphical user interfaces. The housing illumination system 200 can include a processor 202 that can be generally utilized by the portable electronic device for various tasks, function and operations. The housing illumination system 200 can include an illumination controller 204 coupled to the processor 202. The illumination controller 204 operates to control an auxiliary illumination system 206. The auxiliary illumination system 206 produces light 208 that is directed to a surface of a housing 210 of the portable electronic device. The illumination controller 204 can thus, alone or in combination with the processor 202, control illumination of the surface of the housing 210 of the portable electronic device.

The housing illumination system 200 can also include an input/output (I/O) port 212 that can couple to the processor 202. The input/output (I/O) port 212 can enable the portable electronic device and/or the housing illumination system 200 to send or receive data, such as commands, configurations, data or requests, from/to the housing illumination system 200.

The housing illumination system 200 can also include a user input device 214. The user input device 214 can allow a user to enter user input with respect to the portable electronic device. The user input can affect the housing illumination being applied to the housing 210 of the portable electronic device. For example, in response to a user input selection (button press, click, etc.), a portion of the housing can be illuminated to provide visual feedback for the button press. Still further, the housing illumination system 200 can also include a sensor 216. The sensor 216 can pertain to a motion sensor to provide a motion input to the processor 202. The motion input can pertain to motion of the portable electronic device. The motion (or sensor) information can be utilized by the processor 202 or the illumination controller 204 when determining how and when to illuminate a portion of the housing 210 of the portable electronic device.

The housing illumination system 200 can also include or couple to a display controller 218 and a display device 220. The display controller 218 couples to the processor 202 and serves to control the information being displayed on the display device 220. In one embodiment, the display device 220 is a primary display device for the portable electronic device. Typically, the primary display device would be the largest display being utilized by the portable electronic device. According to the housing illumination system 200, the auxiliary illumination source 206 is separate and apart from the display device 220. As a result, advantages of various embodiments of the invention can be provided by the housing illumination system 200 without the need to utilize the display device 220. Instead, through use of the auxiliary illumination source 206, notifications, guidance or other information can be provided to a user of a portable electronic device through use of the auxiliary illumination source 206 instead of the display device 220. Consequently, as an example, if the portable electronic device is presently in a low power mode (e.g., sleep mode) in which the processor 202 can be in a low power state, the auxiliary illumination source 206 can provide visual guidance, alerts or other information to the user of the portable electronic device. In one embodiment, the portable electronic device is able to remain in a low power mode yet still be able to illuminate a portion of its housing using the auxiliary illumination source 206, thereby providing visual guidance, alerts or other information to the user of the portable electronic device in a power efficient manner.

Illumination of the housing of a portable electronic device can be implemented in various different ways. Generally speaking, the illumination can be provided using a single light source, multiple light sources, an integrated light source, or some combination thereof. As an example, a single light source can be a light emitting diode (LED). As another example, multiple light sources can be an arrangement (e.g., grid) of light sources, such as LEDs. As still another example, an integrated light source (e.g., OLED, LCD, backlight display, or pixel display) can be a display screen or touch screen. The one or more light sources can produce light of one or more colors. Still further, the display technology utilized for illumination of the housing can vary, though low powered solutions are advantageous. For example, low power LED, non-emissive displays, zero-power displays

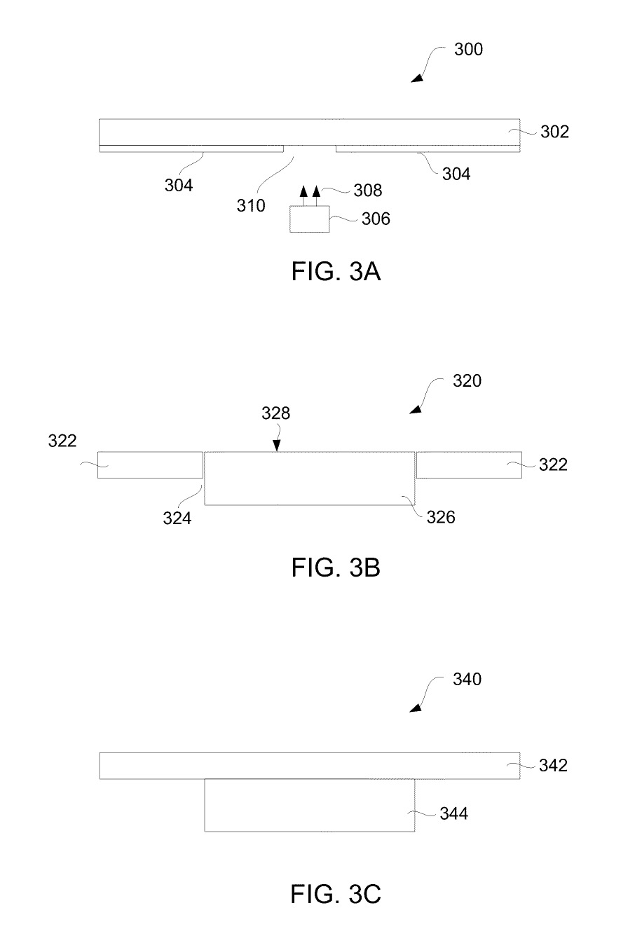

FIGS. 3A-3C are diagrams of exemplary embodiments for illuminating housings of portable electronic devices.

FIG. 3A is a simplified cross-sectional view of a housing illumination arrangement 300 for a portable electronic device according to one embodiment. The housing illumination arrangement 300 includes a housing 302 that serves as an outer housing for the portable electronic device. An inner surface of the housing 302 is provided a mask layer 304. Internal to the housing 302 is a light source 306. The light source 306 produces light 308. The light 308 can be directed toward the inner surface of the housing 302. The mask 304 operates to block or reflect the light 308. However, an opening 310 in the mask 304 allows light to reach the housing 302 and thereby illuminate a portion of the housing 302. The opening 310 in the mask 304 can be configured to provide a predetermined shape or design. By controlling the light source 306, the characteristics (e.g., intensity, color) of the illumination can be controlled in a static or dynamic manner. The light source 306 can represent one or more discrete light sources that can be selectively controlled. In an alternative embodiment, the opening 310 can be replaced by a plurality of micro-perforations that allow light to pass but such micro-perforations are not perceptible when light is not supplied.

FIG. 3B is a simplified cross-sectional view of a housing illumination arrangement 320 for a portable electronic device according to another embodiment. The housing illumination arrangement 320 includes a housing 322 that serves as an outer housing for the portable electronic device. The housing 322 includes an opening 324 for receiving a display 326. The display 326 can have an outer surface 328. The outer surface 328 of the display 326 can be substantially aligned with the outer surface of the housing 322. In one implementation, the outer surface 328 of the display 326 can provide some or all of the outer surface for the portable electronic device. In any event, the display 326 can be used to effectively illuminate at least a portion of the outer surface of the portable electronic device. Since the display 326 can present a wide range of text and graphics (including animations, presentations or videos), the housing can be illuminated as appropriate depending on objectives.

FIG. 3C is a simplified cross-sectional view of a housing illumination arrangement 340 for a portable electronic device according to another embodiment. The housing illumination arrangement 340 includes a housing 342 that serves as an outer housing for the portable electronic device. A display 344 is attached to an inner surface of the housing 342. At least a portion of the housing 342 adjacent the display 344 is at least partially translucent so that light produced by the display 344 can be projected through the housing 342. The display 326 can thus be used to effectively illuminate at least a portion of the outer surface of the portable electronic device. Since the display 344 can present a wide range of text and graphics (including animations, presentations or videos), the housing 342 can be illuminated as appropriate depending on objectives.

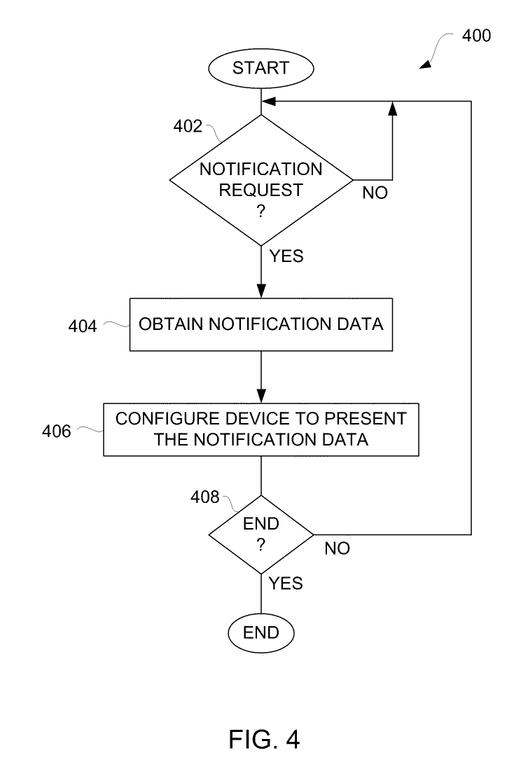

FIG. 4 is a flow diagram of a notification process 400 according to one embodiment of the invention. The notification process 400 can operate to cause a portable electronic device to provide a notification to its user.

The notification process 400 can begin with a decision 402 that determines whether a notification request has been received. Here, the portable electronic device performing the notification process 400 can await a notification request. The notification request can pertain to (i) a user initiated action requesting a notification, (ii) a device initiated action (e.g., programming event), or (iii) a remotely initiated action by another computing device. In any case, when the decision 402 determines that a notification request has not been received, the notification process 400 awaits receipt of such a request. Once the decision 402 determines that a notification request has been received, notification data can be obtained 404. Notification data is data that defines or characterizes the notification to be provided. The notification data can include (i) data to be presented in the notification (text, graphics, etc.), and/or (ii) data on how to present the notification data. Next, the portable electronic device can be configured 406 to present the notification data. For example, the portable electronic device can include a housing that can be illuminated to provide the notification representing the notification data. Hence, the portable electronic device can be configured 406 to illuminate a portion of its housing to provide the notification data to the user. As discussed above, various technologies and implementations can be utilized to permit at least a portion of the housing to be controllably illuminated to provide one or more notifications.

After the portable electronic device has been configured 406 to provide the notification through illumination of at least a portion of its housing, a decision 408 can determine whether the notification process 400 should end. When the decision 408 determines that the notification process 400 should not end, the notification process 400 can return to repeat the decision 402 to await a subsequent notification request. Alternatively, when the decision 408 determines that the notification process 400 should end, the notification process 400 can end.

It should be recognized that notification may only be desired with timely or for a limited period of time. The notification data (e.g., the data on how to present the notification data) can also indicate a duration or an end condition for the presentation of the notification. For example, a previously presented notification can be removed after being presented for the duration or after the end condition has been detected.

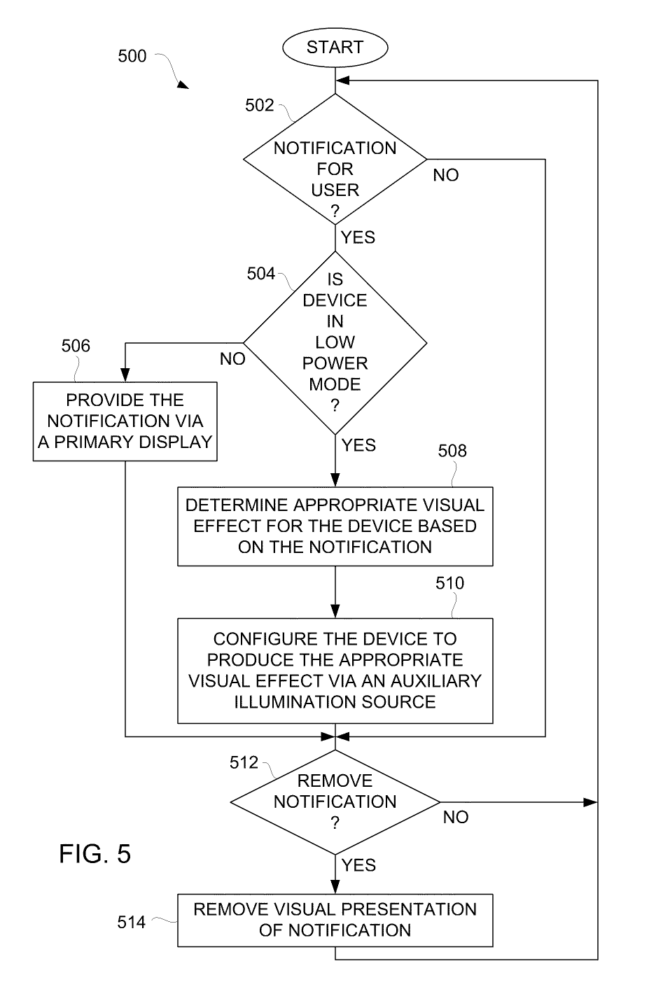

FIG. 5 is a flow diagram of the notification process 500 according to another embodiment of the invention. The notification process 500 can, for example, be performed by any portable electronic device to provide one or more notifications to its users.

The notification process 500 can begin with a decision 502 that determines whether there is a notification to be presented to a user of a portable electronic device. When the decision 502 determines that there is a notification for the user, a decision 504 can determine whether the portable electronic device is in a low-power mode. In this embodiment, it is assumed that the portable electronic device can operate in not only a normal power mode but also a low-power mode in which the device is largely inactive. It is also assumed that the portable electronic device is associated with a primary display as well as an auxiliary illumination source. In one embodiment, when the portable electronic device is used in the low power mode, the primary display is off and not being utilized. However, while in the low-power mode, the auxiliary illumination source can be utilized to provide notifications to the user in a more power efficient manner.

Accordingly, when the decision 504 determines that the portable electronic device is not in the low-power mode, but in the normal power mode, the notification can be provided 506 using the primary display. In this situation, the primary display is active and, therefore, any notification can be presented on a portion of the primary display. On the other hand, when the decision 504 determines that the portable electronic device used in the low-power mode, the notification can be presented to the user using the auxiliary illumination source. In particular, an appropriate visual effect for the portable electronic device can be determined 508 based on the notification. The appropriate visual effect is typically an illuminated effect presented on a housing of the portable electronic device to provide the notification to the user. After the appropriate visual effect has been determined 508, the portable electronic device can be configured 510 to produce the appropriate visual effect using the auxiliary illumination source. By using the auxiliary illumination source, as opposed to using the primary display, the portable electronic device is able to provide the notification to the user while the portable electronic device remains in the low-power mode and the primary display is not utilized.

Following the block 506 or the block 510, a decision 512 can determine whether an existing notification should be removed from the portable electronic device. When the decision 512 determines that an existing notification should not be removed, the notification process 500 can return to repeat the block 502 and subsequent blocks so that additional notifications can be similarly processed. Alternatively, when the decision 512 determines that an existing notification should be removed, the visual presentation of the notification (i.e., the visual effect provided by the auxiliary illumination source) can be removed 514. For example, the notification can be removed 514 after a duration of time or after detection of a condition or event. Following the block 514, the notification process 500 can return to repeat the decision 502 and subsequent blocks so that subsequent notifications can be similarly processed.

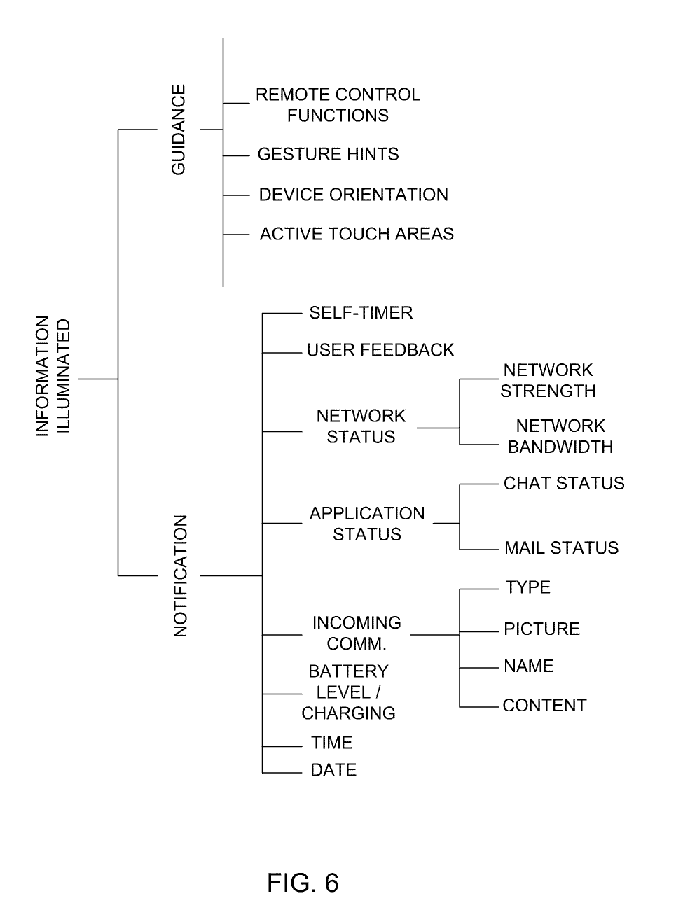

FIG. 6 is diagram describing information that can be illuminated by way of a housing on a portable electronic device. In the information being illuminated as described in FIG. 6 is exemplary of the information that can be illuminated; however, the invention is not limited to illumination of one or more of the information items depicted in FIG. 6.

The information being illuminated by way of a housing of a portable electronic device can pertain to a notification or guidance. With respect to a notification, some examples include: date, time, battery level/charging, incoming communication, application status, network status, user feedback and/or self-timer. Further, with respect to an incoming communication, the notification can, more particularly, pertain to content of the incoming communication, name of the calling party, a picture of the calling party (or picture associated with the calling party), and/or type of communication (e.g., voice, text, chat). Also, with respect to content, the information being illuminated can pertain to the communication, namely, a text message, an electronic mail message, a blog feed, and/or a picture. With respect to application status, the notification can, more particularly, pertained to status of a particular application program, such as a mail status for an electronic mail program or a chat status for a chat application. With respect to network status, the notification can, more particularly, pertain to network bandwidth or network signal strength. With respect to user feedback, the notification can signal to the user that their user input to the portable electronic device has been received. With respect to self-timer, the notification can indicate a timer duration, such as a timer count down for acquiring a picture using a portable electronic device having camera functionality.

With respect to guidance, some examples include: active touch areas, device orientation, gesture hints (gesture guidance), and/or remote control functions. As to active touch areas, the portable electronic device can include a touch surface (e.g., touch screen), and the touch areas that are active can be designated through illumination of portions of the housing. The touch surface can provide one or more virtual controls (e.g., virtual buttons) that are illuminated on the housing of the portable electronic device. Here, the entire surface of the virtual controls can be illuminated or just an outer boundary of the virtual controls can be illuminated. The virtual controls can be controllably provided when such virtual controls are active. For example, if the housing is to provide one or more virtual buttons for user input, the touch surface(s) pertaining to be one or more virtual buttons could be illuminated when such buttons are active. With different applications, modes of use or users, the one or more virtual controls can differ. The ability to illuminate touch areas at appropriate times enables the portable electronic device to dynamically offer virtual controls (e.g., virtual buttons). For example, a portable electronic device could use virtual control to implement a mouse having virtual button and/or a virtual dial, wheel or circular touch surface. With respect to device orientation, a portion of the housing of a portable electronic device can be utilized to illuminate an indication of device orientation. One example of device orientation would be to display a graphical object that conveys to the user the particular orientation for which the portable electronic devices to be used. For example, if the portable electronic device is asymmetrical device, the illuminated indicator can signal the user which end is the front end. As to gesture hints, through illumination of the housing of the portable electronic device, assuming that such housing or a touch screen also supports gesture inputs, such as multi-touch gestures, then the illumination of the portion of the housing can be utilized to provide guidance or hints to users with respect to gestures that are available to be used with the portable electronic device. Hence, with different applications having different modes of operation, different gestures may be available. Also, the gesture hints can assist the user in understanding which gestures are supported via a portable electronic device at any given point in its operation. Still further, as to remote control functions, the illumination of a portion of a housing of the portable electronic device can display virtual controls on the housing that can be utilized by a user to control another electronic device. For example, the housing of the portable electronic device might display media playback commands (e.g., played, applause, fast forward, fast rewind and stop) which the user can interact with to control media playback by the portable electronic device itself or by another electronic device that is remotely located but able to be controlled through use of the portable electronic device.

As discussed above, a housing of a portable electronic device can be illuminated. The illumination can be presented only when relevant or when likely useful. The illumination can be in a single color or in multiple colors. For example, if a housing has a white color, the illumination would use colored light (e.g., blue, black, red, etc.) to illuminate the housing with an indication. As another example, if a housing has a black color, the illumination could use white light to illuminate the housing with an indication.

Although illumination of a portion of a housing is discussed herein, it should be understood that as used herein “illumination” generally refers to providing visual indication(s) or marking(s). Such illumination can by provided by various different technologies. Specifically, illumination can be provided by display technologies that are emissive in that they generate their own light as well as display technologies that rely on external light. One example of an emissive display is a Liquid Crystal Display (LCD). One example of a non-emissive display is electronic ink (E Ink).

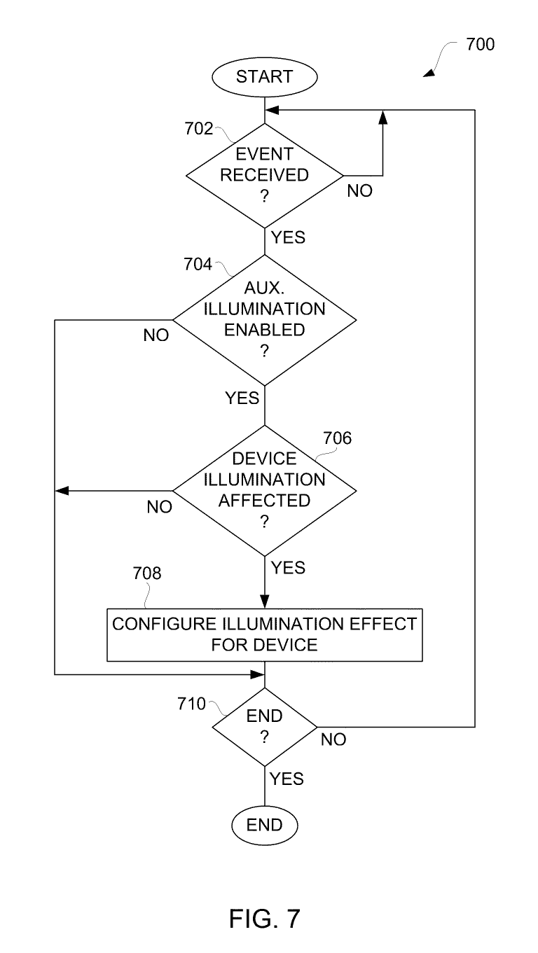

FIG. 7 is a flow diagram of a housing illumination process 700 according to one embodiment of the invention. The housing illumination process 700 is, for example, performed by a portable electronic device that is capable of illuminating at least a portion of its housing. By illuminating at least a portion of its housing, the portable electronic device is able to provide information, instruction and/or guidance to the user of the portable electronic device.

The housing illumination process 700 can begin with a decision 702 that determines whether an event has been received. The event can be associated with a user input event, a remote event or a local event. In any case, when the decision 702 determines that an event has not been received, the housing illumination process 700 can await receipt of such an event. On the other hand, when the decision 702 determines that an event has been received, a decision 704 can determine whether auxiliary illumination has been enabled. Here, in one embodiment, the portable electronic device can be configured such that auxiliary illumination can be enabled or disabled by a user or by another device. For example, a preference setting can be used to enable/disable use of auxiliary information.

When the decision 704 determines that auxiliary illumination is enabled, a decision 706 can determine whether the device illumination is affected by the received event. In some cases, the event received will not induce or cause a change in illumination of the portable electronic device, namely, illumination of the housing of the portable electronic device. When the decision 706 determines that the device illumination is affected by this received event, an illumination effect for the portable electronic device can be configured 708. Here, the illumination effect is the particular illumination to be imposed on the housing of the portable electronic device. The illumination effect is typically based upon the received event. However, in other embodiments, the illumination effect can be dependent upon other criteria such as user input, user preference, sensor input, or remote device input.

Alternatively, when the decision 704 determines that auxiliary illumination is not enabled (i.e., disabled) or when the decision 706 determines that device illumination is not affected, the processing in which the illumination effect is configured 708 can be bypassed. Following the configuration 708 of the illumination effect for the portable electronic device or its being bypassed, a decision 710 can determine whether the housing illumination process 700 should end. When the decision 710 determines that the housing illumination process 700 should not end, the housing illumination process 700 returns to repeat the decision 702 so that subsequent events can be similarly received and processed. Alternatively, when the decision 710 determines that the housing illumination process 700 should end, the housing illumination process 700 ends.

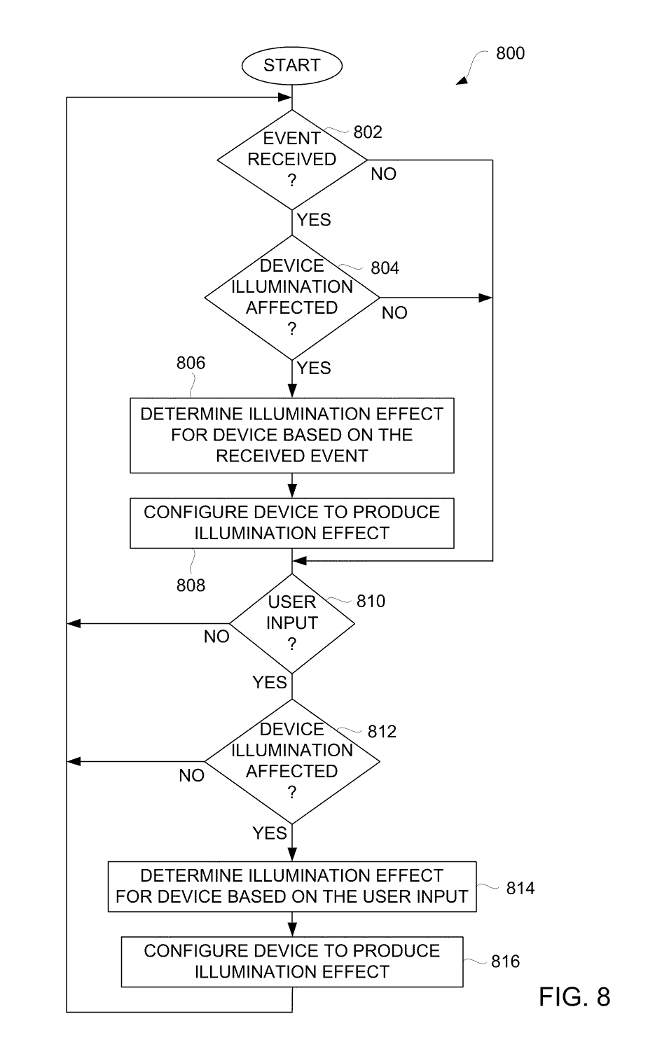

FIG. 8 is a flow diagram of a housing illumination process 800 according to another embodiment of the invention. The housing illumination process 800 is, for example, performed by a portable electronic device that is capable of illuminating at least a portion of its housing. By illuminating at least a portion of its housing, the portable electronic device is able to provide information, instruction and/or guidance to the user of the portable electronic device.

The housing illumination process 800 can begin with a decision 802 that determines whether an event has been received. The event can be associated with a user input event, a remote event or a local event. When the decision 802 determines that an event has been received, a decision 804 can determine whether illumination of the portable electronic device is affected by the received event. When the decision 804 determines that illumination of the portable electronic device is affected by the received event, an illumination effect for the portable electronic device can be determined 806 based on the received event. The portable electronic device can then be configured 808 to produce the illumination effect. Here, the portable electronic device can include one or more internal light sources that are able to be selectively controlled to illuminate an appropriate portion of the housing of the portable electronic device to provide the desired illumination effect. Alternatively, when the decision 804 determines that illumination of the portable electronic device is not affected, the blocks 806 and 808 can be bypassed.

Following the block 808 or its being bypassed, the housing illumination process 800 can perform a decision 810 that determines whether a user input has been received. Further, when the decision 802 determines that an event has not been received, the housing illumination process 800 can proceed to the decision 810 to determine whether a user input has been received. When the decision 810 determines that a user input has not been received, the housing illumination process 800 can return to repeat the decision 802 so that subsequent events or user inputs can be similarly processed. On the other hand, when the decision 810 determines that a user input has been received, a decision 812 can determine whether illumination of the portable electronic device is affected by the user input. If the decision 812 determines that the illumination of the portable electronic device is affected, an illumination effect for the portable electronic device can be determined 814 based on the user input. The illumination effect can replace, eliminate or be in addition to the illumination effect configured in block 808. The portable electronic device can then be configured 816 to produce the illumination effect. Following the block 816, the housing illumination process 800 can return to repeat the decision 802 so that subsequent events or user inputs can be similarly processed.

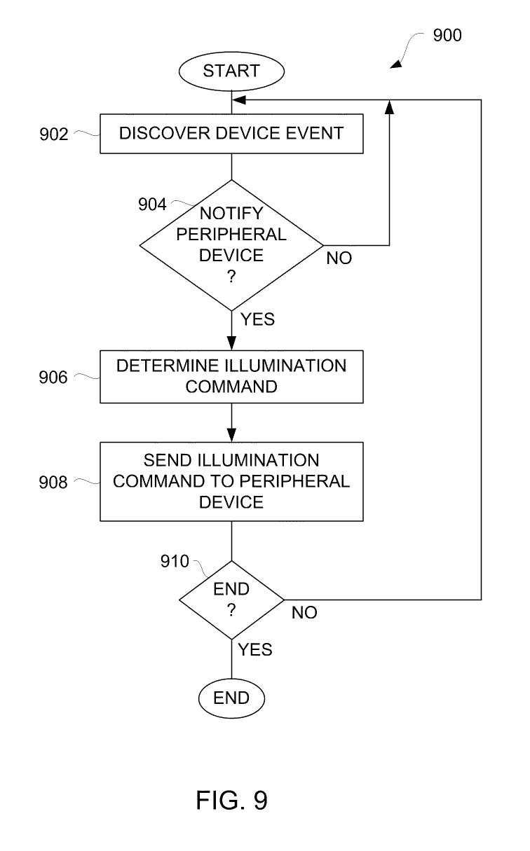

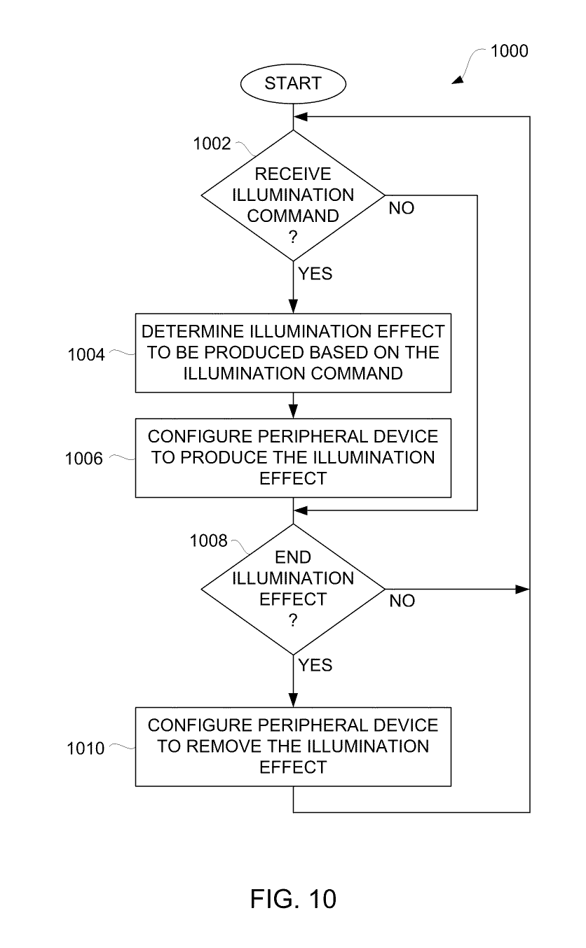

In one embodiment, the portable electronic device being illuminated can pertain to a peripheral device. The peripheral device is an electronic device that can couple to a host device, such as a host computer, to provide the host computer with additional functionality. For example, the peripheral device can pertain to a user input device, such as a pointing device (mouse, trackball, etc.). Furthermore, illumination of the peripheral device can be fully or partially controlled by the host device. FIGS. 9 and 10 illustrate illumination processing for a host device and a peripheral device, respectively.

FIG. 9 is a flow diagram of a host illumination process 900 according to one embodiment of the invention. The host illumination process 900 can be implemented by a host device that controls illumination on a peripheral device that can be coupled to the host device.

The host illumination process 900 can initially discover 902 a device event. The device event is an event that is recognized at the host device for action at the peripheral device. A decision 904 can determine whether the peripheral device is to be notified of the device event. For example, the device event can pertain to events for the host device as well for the peripheral device. The peripheral device can be notified of those of the device events that pertain to the peripheral device. When the decision 904 determines that the peripheral device is not to be notified of the device event that has been discovered 902, the host illumination process 900 can return to repeat the block 902. On the other hand, when the decision 904 determines that the peripheral device is to be notified of the device event has been discovered 902, an illumination command can be determined 906. In one implementation, the illumination command can be determined 906 based on one or more of: peripheral device capability, device event, host device and/or peripheral device configuration, or application or mode of operation at the host device and/or peripheral device. In any event, after the illumination command has been determined 906, the illumination command can be sent 908 to the peripheral device.

Thereafter, a decision 910 can determine whether the host illumination process 900 should end. When the decision 910 determines that the host illumination process 900 should not end, the host illumination process 900 can return to repeat the block 902 and subsequent blocks. Alternatively, when the decision 910 determines that the host illumination process 900 should end, then the host illumination process 900 can end.

FIG. 10 is a flow diagram of a peripheral illumination process 1000 according to one embodiment of the invention. The peripheral illumination process 1000 is, for example, performed by a peripheral device. The peripheral illumination process 1000 can, for example, represent peripheral-side processing that can be performed as a counterpart to the host illumination process 900 illustrated in FIG. 9.

The peripheral illumination process 1000 can, for example, begin with a decision 1002 that determines whether an illumination command has been received. Here, the illumination command can be received from a host device, such as a host computer, that performs the host illumination process 900 illustrated in FIG. 9. When the decision 1002 determines that an illumination command has been received, an illumination effect to be produced can be determined 1004 based on the illumination command. Here, the illumination command can contain data that is utilized to determine 1004 the appropriate illumination effect to be produced on the housing of the peripheral device. In one embodiment, the illumination command can include one or more of: content for display, position/placement/portion for illumination, duration, or other characteristics. Hence, the illumination command can not only control what is displayed but also where and for how long. Next, the peripheral device can be configured 1006 to produce the illumination effect on the housing of the peripheral device. Alternatively, when the decision 1002 determines that an illumination command has not been received, the blocks 1004 and 1006 can be bypassed.

Following the block 1006 or its being bypassed, a decision 1008 can determine whether the illumination effect being applied to the housing of the peripheral device should end. In one embodiment, when the illumination effect is determined 1004, a duration or timing of visual effects can be set so as to control its presentation. The decision 1008 can make use of such duration or timing to determine whether the illumination effect being applied to the housing of the peripheral device should end. When the decision 1008 determines that the illumination effect being applied should not end, the peripheral illumination process 1000 can return to repeat the decision 1002 so that an illumination command, if received, can be processed. Alternatively, when the decision 1008 determines that the illumination effect being applied to the housing of the portable electronic device should end, then the peripheral device is configured 1010 to remove the illumination effect. Following the block 1010, the peripheral illumination process 1000 can return to repeat the decision 1002 so that an illumination command, if received, can be processed.

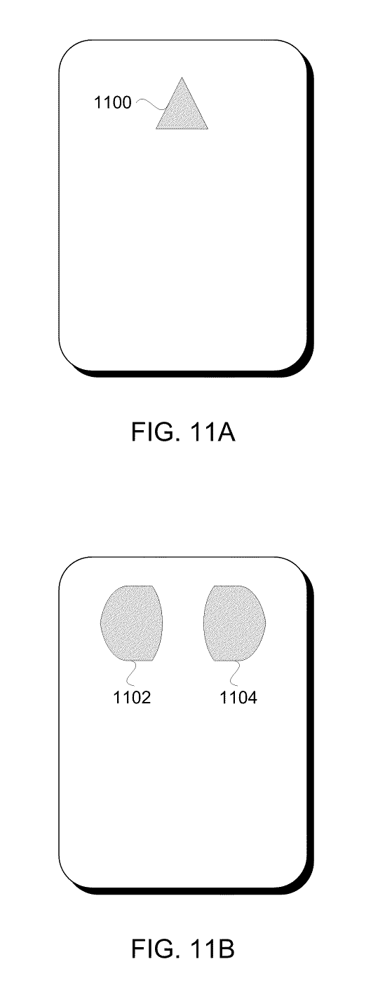

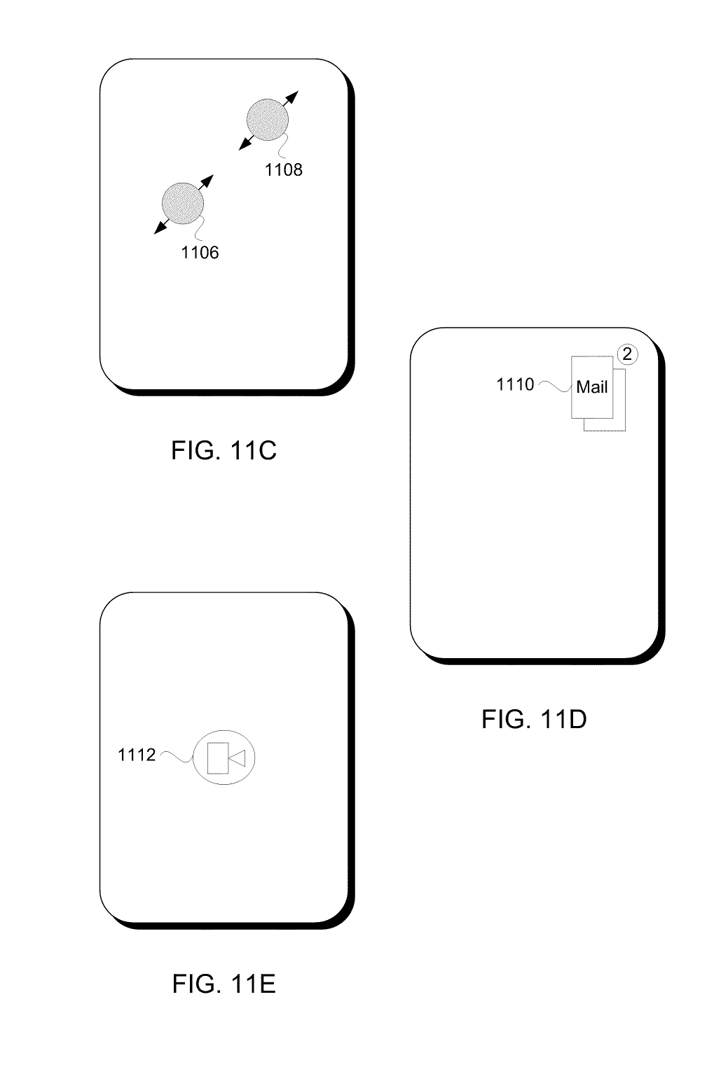

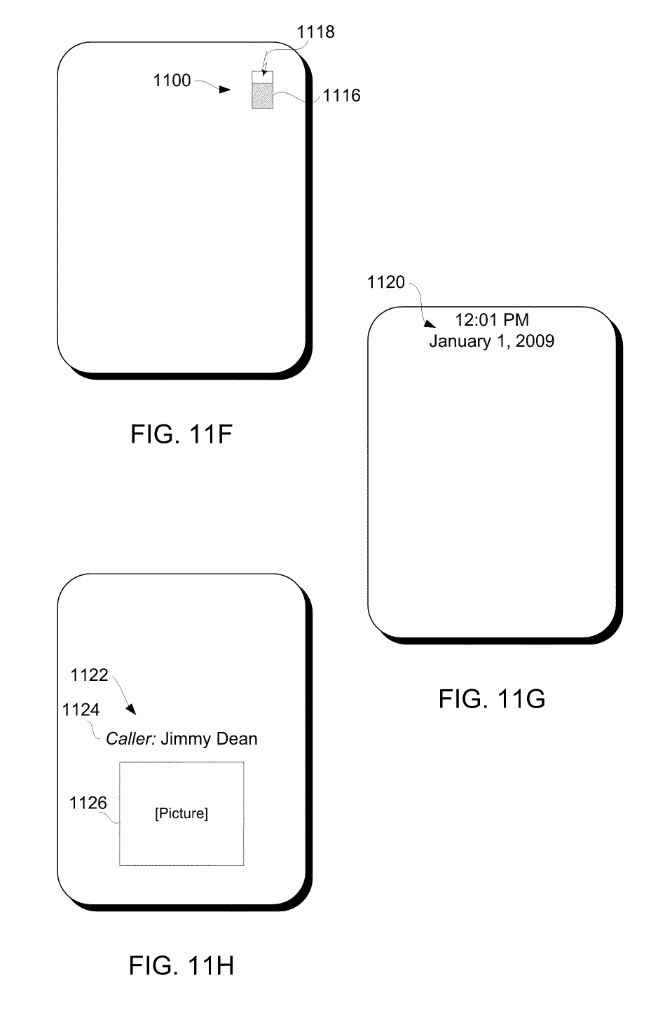

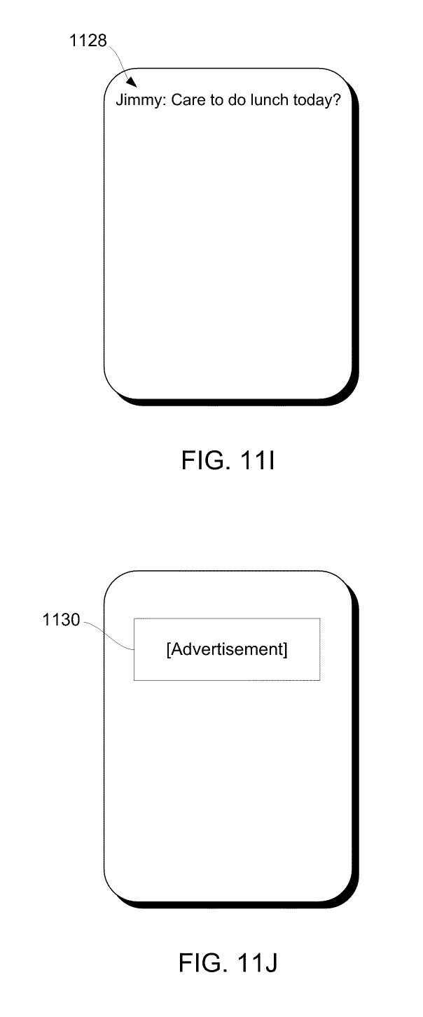

FIGS. 11A-11J are diagrams illustrating exemplary illuminations that can be provided on a housing of a portable electronic device according to various embodiments. The exemplary illuminations can, for example, represent implementations of information suitable for illumination such as illuminated in FIG. 6. FIGS. 11A-11J illustrate a top view of a representative housing surface having exemplary illuminations. The representative housing surface can pertain to a front, side, top, bottom or back surface of a portable electronic device. The exemplary illuminations can also be provided on more than one housing surface. The amount of available illumination for a housing surface depends on implementation. However, in some cases only a small region is needed to provide exemplary illuminations, while in other cases an extensive portion of a surface is needed to provide exemplary illuminations.

FIG. 11A illustrates a top view of a representative housing surface of a portable electronic device according to one embodiment. As shown in FIG. 11A, an orientation indicator 1100 can be illuminated on the representative housing of the portable electronic device. The orientation indicator 1100 can serve to assist a user with orienting the portable electronic device for usage. As one example, when movement of the portable electronic is detected, the orientation indicator 1100 can be provided, and when movement is not detected, the orientation indicator 1100 can not be provided.

FIG. 11B illustrates a top view of a representative housing surface of a portable electronic device according to another embodiment. As shown in FIG. 11B, first and second virtual buttons 1102 and 1104 are depicted as being illuminated on the representative housing surface of the portable electronic device. Additionally, when the first and second virtual buttons 1102 and 1104 are being active or not needed, the illumination of the first and second virtual buttons 1102 and 1104 can be stopped such that the first and second virtual buttons 1102 and 1104 are not discernable on the representative housing of the portable electronic device. As one example, the first and second virtual buttons 1102 and 1104 can be presented to enable the representative housing surface to operate as a user input device, such as a “mouse”. The particular illumination applied to render the first and second virtual buttons 1102 and 1104 can vary from illumination of the while button surface to illumination of only the boundaries of the first and second virtual buttons 1102 and 1104.

FIG. 11C illustrates a top view of a representative housing surface of a portable electronic device according to another embodiment. As shown in FIG. 11C, a multi-touch gesture hint is illuminated on the representative housing surface. It is assumed that the representative housing surface supports multi-touch inputs, such as with a touch sensitive surface. More specifically, the multi-touch gesture hint being illuminated includes a first touch indicator 1106 and a second touch indicator 1108. The first and second touch indicators 1106 and 1108 together provide the multi-touch gesture hint, which in this instance signals a user that a multi-touch “pinch” gesture can be utilized by touching the surface with two fingers and moving them together or apart. For example, the multi-touch “pinch” gesture he can be utilized to zoom in or zoom out of an object or document.

FIG. 11D illustrates a top view of a representative housing surface of a portable electronic device according to another embodiment. As shown in FIG. 11D, a mail status indicator 1110 can be depicted on a portion of the housing of the portable electronic device. In this example, the mail status indicator 1110 indicates that the user of the portable electronic device has received two new e-mail messages in their electronic mail box. The mail status indicator 1110 can pertain to a graphical icon.

FIG. 11E illustrates a top view of a representative housing surface of a portable electronic device according to another embodiment. As shown in FIG. 11E, a chat request indicator 1112 can be depicted on a portion of the housing of the portable electronic device. In this example, the chat request indicator 1112 indicates that the user of the portable electronic device has received a chat request. The mail status indicator 1112 can pertain to a graphical icon.

FIG. 11F illustrates a top view of a representative housing surface of a portable electronic device according to another embodiment. As shown in FIG. 11F, a battery status indicator 1114 can be depicted on a portion of the housing of the portable electronic device. The battery status indicator 1114 can indicate a battery charge level through use of a charge level indicator 116. Additionally, a charging indicator 118 can also be illuminated in the case in which the battery of the portable electronic device is currently being charged (e.g. by way of a power adapter coupled to an AC outlet).

FIG. 11G illustrates a top view of a representative housing surface of a portable electronic device according to another embodiment. As shown in FIG. 11G, a time/date indicator 1120 can illuminate a portion of the housing of the portable electronic device to indicate time of day and/or date, namely, current time and date.

FIG. 11H illustrates a top view of a representative housing surface of a portable electronic device according to another embodiment. As shown in FIG. 11H, a call indicator 1122 can be illuminated on a portion of the housing portable electronic device, such as when an incoming call is being received by the portable electronic device. In the call indicator 1122 can include a caller name indication 1124 that illuminates a portion of the housing to indicate the name of the incoming caller. The call indicator 1122 can also, in some cases, illuminate a portion of the housing to provide a caller image indication 1126 (e.g., such as a picture of the caller). Alternatively or additionally, the call indicator 1122 could indicate a caller-ID associated with the incoming call.

FIG. 11I illustrates a top view of a representative housing surface of a portable electronic device according to another embodiment. As shown in FIG. 11I, a text indicator 1128 can illuminate a portion of the housing of the portable electronic device with text to be presented to the user of the portable electronic device. The text indicator 1128 can pertain to a SMS message, a electronic mail message, a text message, a blog entry, and the like.

FIG. 11J illustrates a top view of a representative housing surface of a portable electronic device according to another embodiment. As shown in FIG. 11J, an advertisement 1130 can illuminate a portion of the housing of the portable electronic device. The advertisement 1130 can advertise a product or surface. The advertisement 1130 can also be refreshed or selected depending on usage, location, user, or the like.

The illumination of a portion of a housing as discussed above can be illuminated in a discrete manner, i.e., either on or off. Such illumination can be always on, on if active, on if appropriate, on if movement, or on if touched. The illumination of a portion of a housing as discussed above can also be illuminated in a dynamic manner. For example, the illumination can provide a visual effect. For example, pulsing illumination can be provided, such as on a virtual control for user input. As another example, dynamic illumination, such as an animation, for visual distinctiveness or for conveying different information can be provided. On example of a dynamic illumination is a ripple effect that is illumination following a user input such as with a virtual control.

The advantages of the invention are numerous. Different aspects, embodiments or implementations may, but need not, yield one or more of the following advantages. One advantage of one certain embodiments of the invention is that the notifications or guidance can be provided even though in a portable electronic device is in a low-power state. Another advantage of certain embodiments of the invention is that auxiliary illumination devices can be provided within a portable electronic device and operable to provide notifications with low power consumption. For example, portable electronic devices or associated host computers can remain completely or primarily in a low-power state, such as a sleep state, yet can still provide notifications. Still another advantage of certain embodiments of the invention is that a portable electronic device being illuminated can pertain to a peripheral device, and illumination of the peripheral device can be fully or partially controlled by the host device.

The portable electronic device described herein can be a multi-function portable electronic device. For example, the multi-function portable electronic device can support wireless communication (e.g., mobile phone) and media playback (e.g., portable media player) capabilities. More generally, the multi-function portable electronic device can support two or more of: wireless communication, media playback, electronic mail, text messaging, electronic chat, scheduling, network access (e.g., Internet), application execution, etc.

The portable electronic device described herein may be a hand-held electronic device. The term hand-held generally means that the portable electronic device has a form factor that is small enough to be comfortably held in one hand. Typically, the hand-held electronic device is lightweight and highly portable. A hand-held electronic device may be directed at one-handed operation or two-handed operation. In one-handed operation, a single hand is used to both support the device as well as to perform operations with the user interface during use. In two-handed operation, one hand is used to support the device while the other hand performs operations with a user interface during use or alternatively both hands support the device as well as perform operations during use. In some cases, the hand-held electronic device is sized for placement into a pocket of the user. By being pocket-sized, the user does not have to directly carry the device and therefore the device can be taken almost anywhere the user travels (e.g., the user is not limited by carrying a large, bulky and often heavy device).

This application also references and/or incorporates U.S. Pat. No. 7,452,098, which is hereby incorporated herein by reference.

The various aspects, features, embodiments or implementations of the invention described above can be used alone or in various combinations.

Embodiments of the invention can, for example, be implemented by software, hardware, or a combination of hardware and software. Embodiments of the invention can also be embodied as computer readable code on a computer readable medium. The computer readable medium is any data storage device that can store data which can thereafter be read by a computer system. Examples of the computer readable medium generally include read-only memory and random-access memory. More specific examples of computer readable medium are tangible and include Flash memory, EEPROM memory, memory card, CD-ROM, DVD, hard drive, magnetic tape, and optical data storage device. The computer readable medium can also be distributed over network-coupled computer systems so that the computer readable code is stored and executed in a distributed fashion.

In the foregoing description, reference to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams representing one or more embodiments of the invention do not inherently indicate any particular order nor imply any limitations in the invention.

The many features and advantages of the present invention are apparent from the written description. Further, since numerous modifications and changes will readily occur to those skilled in the art, the invention should not be limited to the exact construction and operation as illustrated and described. Hence, all suitable modifications and equivalents may be resorted to as falling within the scope of the invention.

What is claimed is:

1. A method for utilizing an outer surface of a housing of a portable electronic device, said method comprising:
receiving a notification request;
obtaining notification data; and
presenting the notification data to the user of the portable electronic device using a portion of the outer surface of the housing of the portable electronic device.

2. A method as recited in claim 1, wherein the portable electronic device includes a primary display screen, and wherein the portion of the outer surface of the housing is separate and distinct from the primary display screen.

3. A method as recited in claim 1, wherein the portable electronic device include at least one user input device, and wherein said receiving of the notification request receives the notification request from the at least one user input device.

4. (canceled)

5. (canceled)

6. (canceled)

7. A method as recited in claim 1, wherein said receiving of the notification request receives the notification request from a software component operating on the computer, and wherein the notification data is determined based on an instruction or command from the computer.

8. (canceled)

9. (canceled)

10. (canceled)

11. A method as recited in claim 1, wherein said method further comprises:
detecting movement of the portable electronic device; and
issuing a notification request based on the detection of movement of the portable electronic device.

12. A method as recited in claim 11, wherein said presenting of the notification data operates to present the notification data on the outer surface of the housing of the portable electronic device only a predetermined amount of time unless additional movement of the portable electronic device is detected.

13. (canceled)

14. A method for illuminating a housing of a portable device capable of receiving user input, said method comprising:
receiving an event at the portable device;
determining whether auxiliary illumination imposed on the housing of the portable device is affected by the event; and
configuring an illumination effect for a portion of the housing of the portable device if the auxiliary illumination imposed on the housing of the portable device is affected by the event, the illumination effect providing auxiliary illumination to the portion of the housing of the portable device.

15. (canceled)

16. (canceled)

17. (canceled)

18. (canceled)

19. (canceled)

20. (canceled)

21. A method as recited in claim 14, wherein the illumination effect provides visual gesture guidance to the user of the portable device.

22. A method as recited in claim 14, wherein the illumination effect provides a visual indication of orientation for the portable device.

23. (canceled)

24. A method as recited in claim 14, wherein the illumination effect provides an indication of a placement of at least one button on the housing of the portable device.

25. (canceled)

26. A method as recited in claim 14, wherein when the illumination effect does not visually denote a user input control region on the housing of the portable device, the user input control region is not visually perceptible.

27. (canceled)

28. (canceled)

29. (canceled)

30. (canceled)

31. (canceled)

32. (canceled)

33. (canceled)

34. (canceled)

35. A portable electronic device, comprising:
a housing for said portable electronic device;
at least one light source on or internal to the housing; and
an illumination controller operatively connected to the at least one light source, said illumination controller dynamically controls the at least one light source to illuminate a portion of the housing.

36. (canceled)

37. A portable electronic device as recited in claim 35, wherein said portable electronic device is a computer peripheral product,
wherein said computer peripheral product comprises a user pointing device for use with a computer system, and
wherein control of the illumination of the portion of the housing is dependent on a user input provided via the user pointing device.

38. (canceled)

39. (canceled)

40. (canceled)

41. A portable electronic device as recited in claim 35,
wherein said portable electronic device further comprising:
a sensor for sensing motion of said portable electronic device, and
wherein the illumination controller is coupled to the sensor, and wherein control of the illumination of the portion of the housing is dependent on motion of said portable electronic device.

42. (canceled)

43. A portable electronic device as recited in claim 35, wherein said portable electronic device further comprises:
a communications port configured to receive an illumination command from a host device, and
wherein control of the illumination of the portion of the housing is dependent on the illumination command received from the host device via the communication port.

44. A portable electronic device as recited in claim 35, wherein said portable electronic device further comprises:
a display device configured to present at least one graphical user interface.

45. A method for marking an outer surface of a housing of a peripheral user input device for use with a computer, said method comprising:
receiving a marking request from the computer; and
electronically marking a portion of the outer surface of the housing of the peripheral user input device in response to the received marking request.

46. A method as recited in claim 45, wherein said electronically marking comprises illuminating the portion of the outer surface of the housing of the peripheral user input device based on the received marking request.

47. (canceled)

48. A method as recited in claim 45, wherein said electronically marking uses electronic ink.

49. (canceled)

50. (canceled)

51. A method as recited in claim 49, wherein said electronically marking of the portion operates to present a gesture reference on the outer surface of the housing.

52. (canceled)

53. A method as recited in claim 45, wherein said method further comprises:
determining the portion of the outer surface of the housing of the peripheral user input device to be marked based on the received illumination request.

54. A method for marking an outer surface of a housing of a peripheral user input device for use with a computer, said method comprising:
receiving a sensor input from a sensor provided with the peripheral user input device; and
electronically marking a portion of the outer surface of the housing of the peripheral user input device based on the received sensor input.

55. (canceled)

56. A method as recited in claim 54, wherein said electronically marking uses electronic ink.

57. (canceled)

58. A method as recited in claim 54, wherein the sensor is internal to the peripheral user input device.

59. (canceled)

60. A method as recited in claim 54, wherein said electronically marking of the portion operates to present a logo or graphical image on the outer surface of the housing that indicates orientation of the peripheral user input device.
